(19) United States
(12) Patent Application Publication
(10) Pub. No.: US 2009/0166736 A1
(43) Pub. Date: Jul. 2, 2009

(54) LATERAL DOUBLE DIFUSED METAL OXIDE SEMICONDUCTOR TRANSISTOR AND METHOD FOR MANUFACTURING THE SAME

(76) Inventor: Il-Yong Park, Seo-gu (KR)

Correspondence Address: SHERR & VAUGHN, PLLC, 620 HERNDON PARKWAY, SUITE 200, HERNDON, VA, 20170, US

(21) Appl. No.: 12/344,544

(22) Filed: Dec. 28, 2008

(30) Foreign Application Priority Data
Dec. 28, 2007 (KR) 10-2007-0139979

(51) Int. Cl. H01L 29/808; H01L 21/336; B05C 11/00

(52) U.S. Cl. 257/343; 438/286; 118/506; 257/E29.261; 257/E21.435

(57) ABSTRACT

A lateral double diffused metal oxide semiconductor a lateral double diffused metal oxide semiconductor (LDMOS) transistor which may include a first conductive type semiconductor substrate and a shallow trench isolation film defining an active region in the substrate. A second conductive type body region may be disposed over a portion of the top of the semiconductor substrate. A first conductive type source region may be disposed in the top of the body region. A first conductive type extended drain region may be disposed over a portion of the top of the semiconductor substrate and spaced from the body region. A gate dielectric film covers surfaces of the second conductive type body region and first conductive type source region and a portion of the top of the first conductive type semiconductor substrate. A gate conductive film may extend from the first conductive type source region, over the gate dielectric film, over the shallow trench isolation film, and inside the shallow trench isolation film. Therefore, embodiments prevent the disturbance in flow of current in an on-state by the STI, making it possible to obtain improved on-state resistance characteristics.

The present application claims priority under 35 U.S.C. 119 to Korean Patent Application No. 10-2007-0139979 (filed on Dec. 28, 2007), which is hereby incorporated by reference in its entirety.

### BACKGROUND

With the improvement in the integration of semiconductor devices and development of corresponding manufacturing design techniques, there is a major effort to consolidate an entire semiconductor system on a semiconductor chip. One chip systems have been developed which unify a controller, a memory and other circuits operating at low voltage into one chip.

However, to make the system small and light, circuitry controlling the power of the system, that is, an input terminal, an output terminal and circuitry performing main functions should be integrated on one chip. Since the input terminal and output terminal are high voltage circuits, they cannot be made the same way as general low voltage CMOS circuits. The input and output terminals are constituted by high voltage power transistors.

Therefore, to reduce size and weight of the system, the input/output terminals of power circuits and the controller should be made on one chip. This is possible with a power IC technique in which a high transistor and a low voltage CMOS transistor circuit are constituted using one chip.

The technique for the power IC is to improve a vertical DMOS (VDMOS) device structure that is a related discrete power transistor. With such a technique, a lateral DMOS (LDMOS) device can be implemented. The LDMOS device is capable of securing high breakdown voltage by disposing a drain horizontally, and having a drift region between a channel region and the drain region, to allow current to flow horizontally.

Using design rules below 0.25 μm, a device isolation film formed in the LDMOS device has a shallow trench isolation (STI) structure instead of a local oxidation of silicon (LOCOS) structure, to increase the density of a logic device. The lateral double diffused metal oxide semiconductor transistor having a related STI structure described above will be described with reference to FIG. 1.

FIG. 1 is a cross-sectional view illustrating a related lateral double diffused metal oxide semiconductor (LDMOS) transistor having a shallow trench isolation (STI) structure. Referring to FIG. 1, an n type semiconductor substrate 10 has a activation region defined by a trench device isolation (STI) film 11. A p type body region 12 and an n− type extended drain region 13 are spaced from each other at a predetermined distance. On the top of the p type body region 12, an n+ type source region 14 is disposed. A portion of the top of the p type body region 12, which is adjacent to the n+ type source region 14 and overlaps with a gate dielectric film 16 and a gate conductive film 17, is a channel region. An n+ type drain region 15 is disposed over the top of the n− type extended drain region 13. The gate dielectric film 16 and gate conductive film 17 are stacked sequentially over the channel region, and gate spacer films 18 are formed over side walls of the gate dielectric film 16 and gate conductive film 17. The n+ type source region 14 and n+ type drain region 15 are electrically connected to a source electrode S and a drain electrode D, respectively, through common wires.

However, in the related lateral double diffused metal oxide semiconductor transistor having an STI structure, the shallow trench isolation film 11 exists between the source and drain, and the gate 17 is extended from the source region 14 to a portion of the trench device isolation film 11. Therefore, when the lateral double diffused metal oxide semiconductor transistor is turned on, the flow of current is disturbed by the shallow trench isolation film 11, causing an undesirable increase in on-state resistance.

### SUMMARY

Embodiments relate to a semiconductor device and a method for manufacturing the same, and more particularly to a lateral double diffused metal oxide semiconductor transistor having improved on-state resistance characteristics and a method for manufacturing the same. Embodiments relate to a lateral double diffused metal oxide semiconductor (LDMOS) transistor which may include a first conductive type semiconductor substrate and a shallow trench isolation film defining an active region in the substrate. A second conductive type body region may be disposed over a portion of the top of the semiconductor substrate. A first conductive type source region may be disposed in the top of the body region. A first conductive type extended drain region may be disposed over a portion of the top of the semiconductor substrate and spaced from the body region. A gate dielectric film covers surfaces of the second conductive type body region and first conductive type source region and a portion of the top of the first conductive type semiconductor substrate. A gate conductive film may extend from the first conductive type source region, over the gate dielectric film, over the shallow trench isolation film, and inside the shallow trench isolation film.

Embodiments relate to a method for manufacturing a lateral double diffused metal oxide semiconductor (LDMOS) transistor which includes: forming a shallow trench isolation film defining an active region in a first conductive type semiconductor substrate; forming a second conductive type body region over a portion of the top of the semiconductor substrate; forming a first conductive type source region in the top of the body region; forming a first conductive type extended drain region over a portion of the top of the semiconductor substrate to be spaced from the body region; forming a gate dielectric film covering surfaces of the second conductive type body region and first conductive type source region and a portion of the top of the first conductive type semiconductor substrate; and forming a gate conductive film extending from the first conductive type source region, over the top of the gate dielectric film, over the top of the shallow trench isolation film, and inside the shallow trench isolation film.

### DRAWINGS

FIG. 1 is a cross-sectional view illustrating a related lateral double diffused metal oxide semiconductor (LDMOS) transistor having a shallow trench isolation (STI) structure.

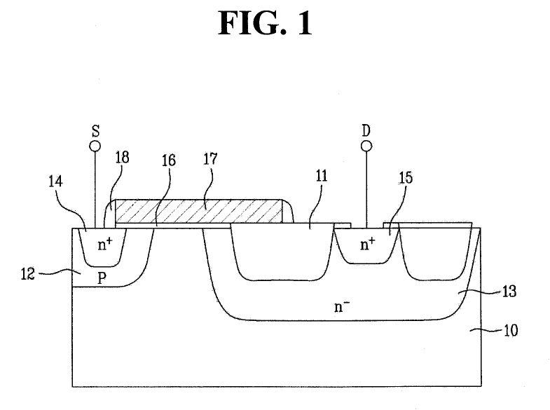

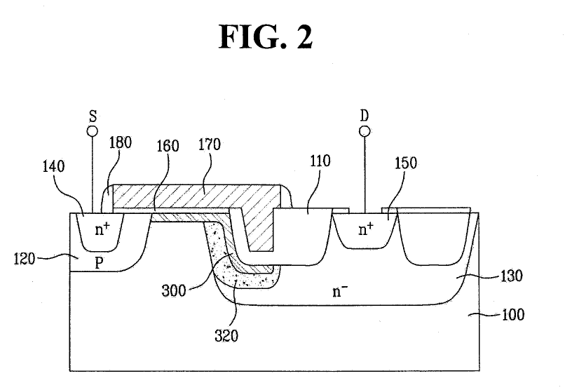

Example FIG. 2 is a cross-sectional view illustrating a lateral double diffused metal oxide semiconductor (LDMOS) transistor according to embodiments.

### DESCRIPTION

Hereinafter, a lateral double diffused metal oxide semiconductor (LDMOS) transistor having a shallow trench isolation (STI) structure according to embodiments will be described in detail with reference to the accompanying drawings. Example FIG. 2 is a cross-sectional view illustrating a lateral double diffused metal oxide semiconductor (LDMOS) transistor having a shallow trench isolation (STI) structure according to embodiments.

As shown in example FIG. 2, an n type semiconductor substrate 100 of the LDMOS transistor having an STI structure according to embodiments may have an active region defined by a shallow trench isolation (STI) film 110. A p type body region 120 may be disposed over a portion of the top of an n type semiconductor substrate 100. An n− type extended drain region 130 may be disposed on a certain region of the top of the n type semiconductor substrate 100, spaced from the p type body region 120 at a predetermined distance. On the top of the p type body region 120, an n+ type source region 140 may be disposed. A portion of the top of the p type body region 120, which is adjacent to the n+ type source region 140 and overlaps with a gate dielectric film 160 and a gate conductive film 170, may serve as a channel region. An n+ type drain region 150 may be disposed at the top of the n− type extended drain region 130.

The gate dielectric film 160 and gate conductive film 170 may be stacked sequentially over the channel region. Gate spacer films 180 may be formed over side walls of the gate dielectric film 160 and gate conductive film 170. More specifically, the gate dielectric film 160 may be disposed covering surfaces of the p type body region 120 and n+ type source region 140 and the top of the n− type semiconductor substrate 100.

Here, the gate conductive film 170 may be formed over the top of the gate dielectric film 160 and a portion of the surface of the shallow trench isolation film 110. The gate conductive film 170 may extend into the inside of a portion of the shallow trench isolation film 110 formed by etching a portion of a side of a source electrode S of the shallow trench isolation film 110. As shown in FIG. 2, the gate dielectric film 160 defines a plane above the substrate 100, and the gate conductive film extends below the plane of the gate dielectric film into the shallow trench isolation film 110. This structure differs from the related structure where the flow of current is disturbed when the transistor is turned on. As shown in FIG. 2, an accumulation layer 300 is formed between silicon and the gate conductive film 170 inside the shallow trench isolation film 100 according to a gate electric field so that on-resistance is reduced.

Here, the thickness of the gate conductive film 170 formed inside the trench device isolation film 110 may be greater than the thickness of the gate conductive film 170 formed over the top surfaces of the gate dielectric film 160 and shallow trench isolation film 110. With this configuration, an electric field between the gate electrode and silicon may be lowered when the transistor is turned off.

The n+ type source region 140 and n+ type drain region 150 may be electrically connected to a source electrode S and a drain electrode D, respectively, through wires. The lateral double diffused metal oxide semiconductor transistor according to embodiments may include an additional n+ type layer 320 extending from the portion below the shallow trench isolation film 110 under the gate conductive film 170 formed inside the shallow trench isolation film 110 to the portion below the gate dielectric film 160. The on-state resistance may thereby further be reduced when the transistor is turned on. In other words, the accumulation layer 300 may be formed between the n+ type additional layer 320 and trench device isolation film 110, and between the semiconductor substrate 100 and gate dielectric film 160.

Hereinafter, a method for manufacturing a lateral double diffused metal oxide semiconductor transistor shown in example FIG. 2 will be described with reference to example FIG. 2. First, a shallow trench isolation film 110 defining an active region may be formed in a first conductive type semiconductor substrate 100.

Thereafter, a second conductive type body region 120 may be formed over a portion of a top of the semiconductor substrate 100. Then, a first conductive type source region 140 may be formed over the top of the body region 120. A first conductive type extended drain region 130 may be formed over a certain region of the top of the semiconductor substrate 100, spaced from the body region 120.

A gate dielectric film 160 may be formed covering surfaces of the second conductive type body region 120 and first conductive type source region 140 and top of the first conductive type semiconductor substrate 100. Next, a gate conductive film 170 may be formed, extending from the first conductive type source region 140, over the gate dielectric film 160, over the top of the shallow trench isolation film 110, and to a certain portion of the inside of the shallow trench isolation film 110. The thickness of the gate conductive film 170 formed inside the shallow trench isolation film 110 may be greater than the gate conductive film 170 formed over surfaces of the gate dielectric film 160 and shallow trench isolation film 110.

The method for manufacturing the lateral double diffused metal oxide semiconductor transistor may further include forming gate spacer films 180 over side walls of the gate conductive film 170 and gate dielectric film 160. Also, the method for manufacturing the lateral double diffused metal oxide semiconductor transistor according to embodiments may further include forming an n+ type additional layer 320 inside the first conductive type extended drain region 130, extending from the portion below the shallow trench isolation film 110 under the gate conductive film 170 formed inside the shallow trench isolation film 110 to the portion below the gate dielectric film 160.

The method for manufacturing the lateral double diffused metal oxide semiconductor transistor according to embodiments may further include forming the accumulation layer 300 between the n+ type additional layer 320 and device isolation film 110, and between the semiconductor substrate 100 and gate dielectric film 160. The first conductive type and second conductive type described above may be an n type and a p type, respectively, or may be reversed.

As described above, the lateral double diffused metal oxide semiconductor transistor and the method for manufacturing the same according to embodiments prevents the disturbance in flow of current by the STI in the on-state, because the gate is formed in a portion of the STI, making it possible to obtain improved on-state resistance characteristics.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. An apparatus comprising:
a first conductive type semiconductor substrate;
a shallow trench isolation film defining an active region in the substrate;
a second conductive type body region disposed over a portion of the top of the semiconductor substrate;
a first conductive type source region disposed in the top of the body region;
a first conductive type extended drain region disposed over a portion of the top of the semiconductor substrate and spaced from the body region;
a gate dielectric film which covers surfaces of the second conductive type body region and first conductive type source region and a portion of the top of the first conductive type semiconductor substrate; and
a gate conductive film extending from the first conductive type source region, over the gate dielectric film, over the shallow trench isolation film, and inside the shallow trench isolation film.

2. The apparatus of claim 1, including:
gate spacer films formed over side walls of the gate conductive film and gate dielectric film.

3. The apparatus of claim 1, wherein a thickness of the gate conductive film formed inside the shallow trench isolation film is greater than a thickness of the gate conductive film formed over surfaces of the gate dielectric film and shallow trench isolation film.

4. The apparatus of claim 1, including:
an n+ type layer, formed inside the first conductive type extended drain region, extending from below the shallow trench isolation film under the gate conductive film formed inside the shallow trench isolation film to a region below the gate dielectric film.

5. The apparatus of claim 4, including:
an accumulation layer extending between the n+ type layer and trench device isolation film, and between the semiconductor substrate and gate dielectric film.

6. The apparatus of claim 1, wherein the first conductive type is an n type and the second conductive type is a p type.

7. The apparatus of claim 1, wherein the first conductive type semiconductor substrate, the second conductive type body region, the first conductive type source region, the first conductive type extended drain region, the gate dielectric film and the gate conductive film form a lateral double diffused metal oxide semiconductor transistor.

8. The apparatus of claim 1, including a first conductive type drain region disposed over the top of the extended drain region.

9. The apparatus of claim 1, wherein the gate dielectric film defines a plane above the substrate, and the gate conductive film extends below the plane of the gate dielectric film.

10. A method comprising:
forming a shallow trench isolation film defining an active region in a first conductive type semiconductor substrate;
forming a second conductive type body region over a portion of the top of the semiconductor substrate;
forming a first conductive type source region in the top of the body region;
forming a first conductive type extended drain region over a portion of the top of the semiconductor substrate to be spaced from the body region;
forming a gate dielectric film covering surfaces of the second conductive type body region and first conductive type source region and a portion of the top of the first conductive type semiconductor substrate; and
forming a gate conductive film extending from the first conductive type source region, over the top of the gate dielectric film, over the top of the shallow trench isolation film, and inside the shallow trench isolation film.

11. The method of claim 10, including:
forming gate spacer films over side walls of the gate conductive film and gate dielectric film.

12. The method of claim 10, wherein a thickness of the gate conductive film formed inside the shallow trench isolation film is greater than a thickness of the gate conductive film formed over surfaces of the gate dielectric film and the shallow trench isolation film.

13. The method of claim 10, including:
forming an n+ type layer inside the first conductive type extended drain region, the n+ type layer extending from below the shallow trench isolation film under the gate conductive film formed inside the shallow trench isolation film to a region below the gate dielectric film.

14. The method of claim 13, including:
forming an accumulation layer between the n+ type additional layer and trench device isolation film, and between the semiconductor substrate and gate dielectric film.

15. The method of claim 10, wherein, together, said forming the shallow trench isolation film, forming the second conductive type body region, forming the first conductive type source region over the top of the body region, forming the first conductive type extended drain region, forming the gate dielectric film, and forming the gate conductive film, includes forming a lateral double diffused metal oxide semiconductor transistor.

16. The method of claim 10, wherein the first conductive type is an n type and the second conductive type is a p type.

17. The method of claim 10, including forming a first conductive type drain region disposed over the top of the extended drain region.

18. The method of claim 10, wherein the gate dielectric film defines a plane above the substrate, and the gate conductive film extends below the plane of the gate dielectric film.

19. An apparatus configured to:
form a shallow trench isolation film defining an active region in a first conductive type semiconductor substrate;
form a second conductive type body region over a portion of the top of the semiconductor substrate;
form a first conductive type source region in the top of the body region;
form a first conductive type extended drain region over a portion of the top of the semiconductor substrate to be spaced from the body region;
form a gate dielectric film covering surfaces of the second conductive type body region and first conductive type source region and a portion of the top of the first conductive type semiconductor substrate; and
form a gate conductive film extending from the first conductive type source region, over the top of the gate dielectric film, over the top of the shallow trench isolation film, and inside the shallow trench isolation film.

20. The apparatus of claim 19 configured to:
form an n+ type layer inside the first conductive type extended drain region, the n+ type layer extending from below the shallow trench isolation film under the gate conductive film formed inside the shallow trench isolation film to a region below the gate dielectric film.
